(19) United States
(12) Patent Application Publication
(10) Pub. No.: US 2015/0368786 A1
(43) Pub. Date: Dec. 24, 2015

(54) METALLIC COATING FIXED STATOR TIP TREATMENT

(71) Applicant: UNITED TECHNOLOGIES CORPORATION, Hartford,, CT (US)

(72) Inventors: Brian S Tryon, Los Gatos, CA (US); Joseph Parkos, East Haddam, CT (US); Russell A Beers, Manchester, CT (US)

(21) Appl. No.: 14/767,272

(22) PCT Filed: Jan. 31, 2014
(86) PCT No.: PCT/US2014/014220

§ 371 Date: Aug. 11, 2015

Related U.S. Application Data
(60) Provisional application No. 61/763,689, filed on Feb. 12, 2013.

(51) Int. Cl. C23C 14/04; C23C 14/06; C23C 14/32

(52) U.S. Cl. CPC C23C 14/042; C23C 14/325; C23C 14/0647

(57) ABSTRACT

A tip region of an airfoil has a wear coating that is deposited using physical vapor deposition in conjunction with a mechanical mask. The mask is positioned with respect to the region portion of the tip to expose only a portion of the tip region to be coated. A physical vapor deposition coating source such as cathode arc (CAT ARC) is used to coat the exposed portion of the tip region with the wear coating.

### BACKGROUND

Gas turbine engine efficiency can be improved by sealing closely mating airfoil tips with air seals. Prior art efforts include depositing an abradable coating on the air seal and allowing the airfoil tips to rub into the coating, thus creating the seal. The drawback to this type of sealing is that the abradable coating can erode or otherwise damage the tips of the blade, thus wearing them down to damage the airfoil and weaken the seal.

### SUMMARY

The present invention provides for a method and system for coating the tip region of an airfoil having a narrow tip within desired thickness tolerance. A mechanical mask is positioned with respect to the tip region of the airfoil to expose only a portion of the tip region to be coated to extend through the mask. Physical vapor deposition (PVD) coating is then employed to coat the exposed tip region.

### BRIEF DESCRIPTION OF THE DRAWINGS

FIG. 1 is a side perspective view of an airfoil having a thin tip and a twisted airfoil.

FIG. 2 is a rear perspective view of an airfoil having a thin tip and a twisted shape.

FIG. 3 is a perspective view of an airfoil fitted with a mechanical mask for physical vapor deposition coating.

### DETAILED DESCRIPTION

For some airfoils, the geometry is unusually thin such that it has not been possible to adequately mask the area not to be coated unless expensive and time consuming processes are used. For example, the entire airfoil may be coated with a mask and then the tip may be plated. However, plated coatings do not have the desired properties, and therefore grit may be sprinkled on during plating. Plasma coating changes the geometry of these airfoils particularly when they have an involved camber and in some cases twists. Control of the tip coating depth has not been successful and more tip is coated than needed.

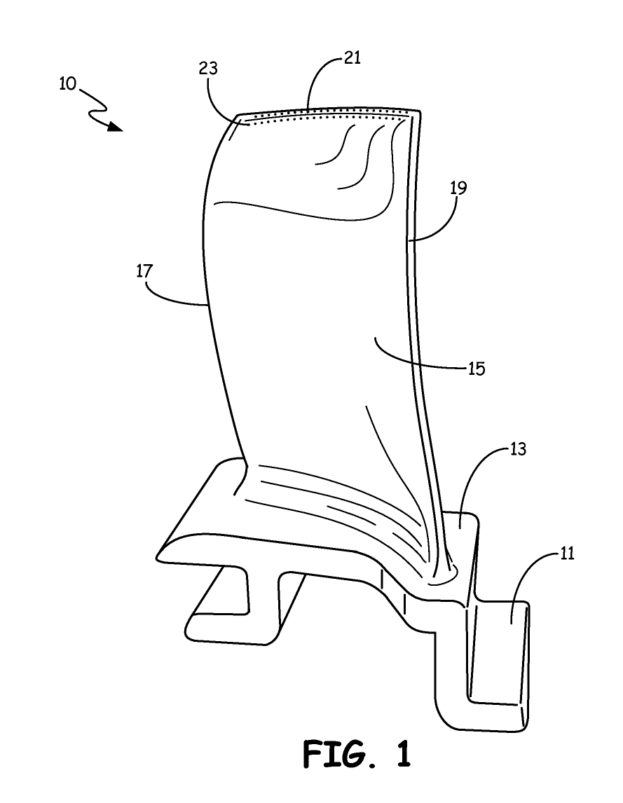

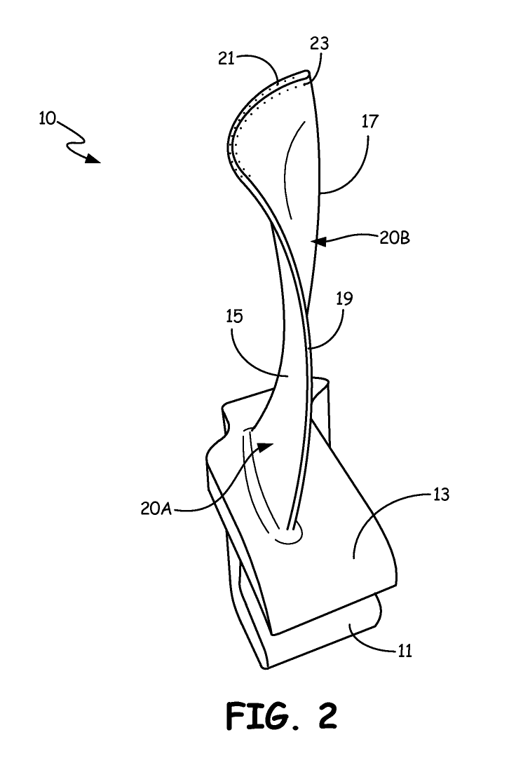

As shown in FIGS. 1 and 2, vane 10 includes mounting hooks 11, platform 13 and airfoil 15. Airfoil 15 includes leading edge 17, trailing edge 19, pressure side 20A, suction side 20B, tip 21, and root 22. Tip 21 has been coated with a wear coating 23, shown by stippling. Vane 10 is designed for use in a gas turbine engine to seal tip 21 with an air seal which in many cases has an abradable coating. Airfoil 15 rubs tip 21 on the abradable coating of the air seal to create an actual seal. Wear coating 23 does not wear down during operation and provides adequate rubbing protection for the air seal and protect the structural integrity of airfoil 15.

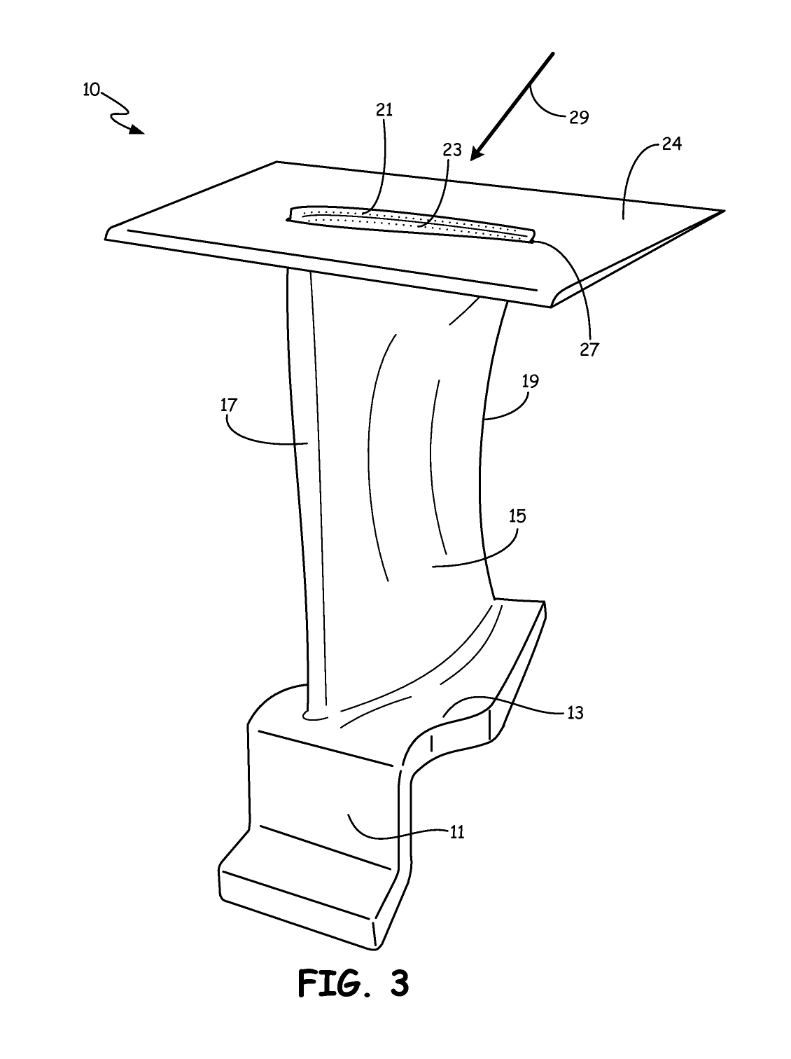

FIG. 3 illustrates the method of coating tip 21, in which mechanical mask 25 is mounted on airfoil 15 to expose only a portion of tip 21 that will be coated with wear coating 23, while shielding the remainder of airfoil 15. Mechanical mask has a narrow slit 27 sized and shaped to allow only that part of tip 21 that is to be coated to be exposed. Mechanical mask 25 prevents any wear coating from contacting blade 15 when a coating is applied in the direction of arrows 29. Mechanical mask 25 is made of metal or other materials that can withstand coating process environments. Mechanical mask 25 has a snug fit on tip 21, thus not needing additional mounting devices. Mechanical mask 25 is generally parallel to the top surface of tip 21 and generally perpendicular to pressure and suction sides 20A and 20B. The coating process uses physical vapor deposition (PVD), such as by CAT ARC (cathode arc) coating using CAT ARC source 31. Of course other forms of deposition can be used, such as sputtering by DC magnetron sputtering and unbalanced magnetron sputtering.

Wear coating 23 ranges from about 1 mil (0.0254 mm) to about 5 mil (0.127 mm) in thickness. Wear coating 23 may be any desired coating material. Wear coating 23 may be selected from the group consisting of stellites, nitrides and carbides. One effective wear coating is cubic boron nitride.

Although vane 10 is shown in FIGS. 1-3, wear coating 23 can also be applied to rotor blades. The method of this invention has been found to be particularly useful for vanes (fixed stators) which wear during operation and are not well suited for conventional wear coating tip treatments. Using the method of this invention, CBN coatings on fixed stators provides rubbing protection for the air seal and protects the structural integrity of the airfoil. The present invention may be used on a plurality of airfoils at the same time so that a tip will be coated for each of the plurality by placing the plurality of airfoils in a common coating device chamber.

The benefits of this invention are that this coating treatment could be easily applied to large numbers of stators at once via CAT ARC, thus reducing the cost per part and alleviating the need to create an expensive chemical methodology for depositing abradable coatings. The CAT ARC process provides a number of potential coating compositions that can be specifically tailored to a given application with no major equipment modifications. Dimensionally the CAT ARC process lends itself well to the use of hard tooling, and that makes the coating deposition repeatable from part to part. CAT ARC coating has a low risk of “slipping” or deteriorating. When chemical masks are used, the masking system can fail. Hard masking as disclosed here is preferable.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

### DISCUSSION OF POSSIBLE EMBODIMENTS

The following are nonexclusive descriptions of possible embodiments of the present invention.

A method of coating a tip region of an airfoil uses a mechanical mask positioned to expose only a portion of the tip region that is to be coated. Physical vapor deposition is used to coat the exposed portion of the tip with a wear coating.

The method of the preceding paragraph can optionally include additionally and/or alternatively, any one or more of the following features, configurations and/or additional components.

The wear coating may be selected from stellites, nitrides and carbides.

The wear coating may be cubic boron nitride.

The mechanical mask is a metallic sheet having a slot sized and shaped to permit the region portion of the tip to extend therethrough.

The amount of wear coating may range from about 1 mil (0.0254 mm) to about 5 mil (0.127 mm) in thickness.

There may be a plurality of airfoils each fitted with a mechanical mask for simultaneous coating of all the airfoil tips.

The physical vapor deposition may be by cathode arc (CAT ARC) deposition.

A system for wear coating a tip region using a mechanical mask positioned with respect to the region portion of the tip to expose only that portion to be coated, and a physical vapor deposition device positioned to coat the exposed portion of the tip region with a wear coating.

The system of the preceding paragraph can optionally include additionally and/or alternatively, any one or more of the following features, configurations and/or additional components.

The wear coating may be selected from stellites, nitrides and carbides.

The wear coating may be cubic boron nitride.

The mechanical mask is a metallic sheet having a slot sized to permit the region portion of the tip to extend there through.

The amount of wear coating may range from about 1 mil (0.0254 mm) to about 5 mil (0.127 mm) in thickness.

There may be a plurality of airfoils each fitted with a mechanical mask for simultaneous coating of all the airfoil tips.

The mechanical mask is generally parallel to a top surface of the tip of the airfoil.

The mechanical mask is generally perpendicular to the pressure and suction sides of the airfoil.

The physical vapor deposition may be by cathode arc (CAT ARC) deposition.

1. A method of coating a tip region of an airfoil, the method comprising:
positioning a mechanical mask with respect to the tip region of the airfoil to expose only a portion of the tip region to be coated; and
physical vapor deposition coating the exposed portion of the tip region with a wear coating.

2. The method of claim 1, wherein the wear coating is selected from the group consisting of stellites, nitrides and carbides.

3. The method of claim 2, wherein the wear coating is cubic boron nitride.

4. The method of claim 1, wherein the mechanical mask is a metallic sheet having a slot sized and shaped to permit the exposed portion of the tip region to extend therethrough.

5. The method of claim 1, wherein the wear coating ranges from about 1 mil (0.0254 mm) to about 5 mil (0.127 mm) in thickness.

6. The method of claim 1, wherein a plurality of airfoils having a narrow tip are each positioned with a mechanical mask exposing only a portion of the tip region to be coated.

7. The method of claim 1, wherein the mechanical mask is generally parallel to the tip.

8. The method of claim 1, wherein the mechanical mask is generally perpendicular to pressure and suction sides of the airfoil.

9. The method of claim 1, wherein the physical vapor deposition coating is by CAT ARC deposition.

10. A system for coating a tip region of an airfoil, the system comprising:
a mechanical mask positioned with respect to the tip region of the airfoil to expose only a portion of the tip region to be coated; and
a physical vapor deposition coating source positioned to coat the exposed portion of the tip region with a wear coating.

11. The system of claim 10, wherein the wear coating is selected from the group consisting of stellites, nitrides and carbides.

12. The system of claim 10, wherein the wear coating is carbon boron nitride.

13. The system of claim 10, wherein the mechanical mask is a metallic sheet having a slot sized and shaped to permit the exposed portion of the tip region to extend therethrough.

14. The system of claim 10, wherein the wear coating ranges from about 1 mil (0.0254 mm) to about 5 mil (0.127 mm) in thickness.

15. The system of claim 10, wherein a plurality of systems having a narrow tip are each positioned with a mechanical mask exposing only a portion of the tip region to be coated.

16. The system of claim 10, wherein the mechanical mask is positioned generally perpendicular to the pressure and suction sides of the airfoil.

17. The system of claim 10, wherein the mechanical mask is positioned generally parallel to a top surface of the tip region.

18. The system of claim 10, wherein the physical vapor deposition source comprises a CAT ARC source.
